(19) United States
(12) Patent Application Publication
(10) Pub. No.: US 2026/0290486 A1
(43) Pub. Date: Sep. 24, 2026

(54) DATA PRESERVATION AFTER A SUPPLY VOLTAGE DECREASE IN A MEMORY SYSTEM

(71) Applicant: Micron Technology, Inc., Boise, ID (US)

(72) Inventors: Chunyu Sheng, Shanghai (CN); Lei Cui, Shanghai (CN); Xiao Wang, Shanghai (CN); Qingyuan Wang, Shanghai (CN)

(21) Appl. No.: 19/559,488

(22) Filed: Mar. 6, 2026

Related U.S. Application Data
(60) Provisional application No. 63/773,984, filed on Mar. 18, 2025.

(51) Int. Cl. G11C 29/50

(52) U.S. Cl. CPC G11C 29/50004; G11C 2029/5004

(57) ABSTRACT

Methods, systems, and devices for data preservation after a supply voltage decrease in a memory system are described. In response to a voltage supply failure, a memory system may write data from a non-retention area of a volatile memory to a retention area of the volatile memory before resetting the memory system, the data intended for storage in a non-volatile memory device of the memory system. After resetting, the memory system may write the data from the retention area of the volatile memory to the non-retention area of the volatile memory. The memory system may then write the data from the non-retention area of the volatile memory to the non-volatile memory device.

### CROSS REFERENCE

The present Application for Patent claims priority to U.S. Patent Application No. 63/773,984 by Sheng et al., entitled “DATA PRESERVATION AFTER A SUPPLY VOLTAGE DECREASE IN A MEMORY SYSTEM,” filed Mar 18, 2025, which is assigned to the assignee hereof, and which is expressly incorporated by reference in its entirety herein.

### TECHNICAL FIELD

The following relates to one or more systems for memory, including data preservation after a supply voltage decrease in a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states if disconnected from an external power source.

### BRIEF DESCRIPTION OF THE DRAWINGS

FIG. 1 shows an example of a system that supports data preservation after a supply voltage decrease in a memory system in accordance with examples as disclosed herein.

FIG. 2 shows an example of a system that supports data preservation after a supply voltage decrease in a memory system in accordance with examples as disclosed herein.

FIG. 3 shows an example of a process flow that supports data preservation after a supply voltage decrease in a memory system in accordance with examples as disclosed herein.

FIG. 4 shows an example of a process flow that supports data preservation after a supply voltage decrease in a memory system in accordance with examples as disclosed herein.

FIG. 5 shows an example of a process flow that supports data preservation after a supply voltage decrease in a memory system in accordance with examples as disclosed herein.

FIG. 6 shows a block diagram of a memory system that supports data preservation after a supply voltage decrease in a memory system in accordance with examples as disclosed herein.

FIG. 7 shows a flowchart illustrating a method or methods that support data preservation after a supply voltage decrease in a memory system in accordance with examples as disclosed herein.

### DETAILED DESCRIPTION

A memory system may have a first voltage supply (e.g., VCCQ) for operating a controller of the memory system and may have a second voltage supply (e.g., VCC) for operating one or more memory devices of the memory system. In some examples, such a memory system may operate in a cache-on write mode in which the memory system confirms to a host system that write data has been stored in the memory devices even though the write data is waiting in a local cache memory to be written to the memory devices. If a memory system is operating in the cache-on write mode and one of the voltage supplies fails (e.g., decreases below a respective threshold level), the memory system may reset and the write data in the local cache memory may be lost. If the host system tries to access the lost write data after the reset, the memory system may fail.

According to the techniques described herein, a memory system may reduce a likelihood such failures occur by preserving the write data (along with various management information for writing the write data to the memory devices) before resetting the memory system. The memory system may determine to preserve the write data and the management information, collectively referred to as “cache data,” if it is determined that the failed voltage supply is the second voltage supply (e.g., VCC) for the operating the memory devices. Preserving the cache data may include copying the cache data from a non-retention area of a local cache memory to a retention area of the local cache memory before the memory system is reset. The memory system may also write a flag to the retention area to indicate the existence of the cache data. After resetting, the memory system may reference the flag, write the cache data back to the non-retention area, then write the write data to the memory devices using the management information. Thus, the write data may be ultimately stored in the memory devices—consistent with the confirmation sent to the host system before the voltage supply failure—even though the write data was in the local cache at the time of the voltage supply failure.

In addition to applicability in memory systems as described herein, techniques for data preservation may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing memory system failures, among other benefits.

In addition to applicability in memory systems as described herein, techniques for data preservation may be generally implemented to support cloud computing and storage applications. As the use of cloud computing to provide processing, storage, and networking services to multiple devices increases, many devices and systems may benefit from improved remote processing and storage capabilities. For example, increasing memory capacity or other capabilities may result in larger and more accessible storage options for users, and increasing memory access times may result in faster processing for computing or database applications. Implementing the techniques described herein may support cloud computing and storages techniques by reducing memory system failures, among other benefits.

Features of the disclosure are illustrated and described in the context of systems, devices, and circuits. Features of the disclosure are further illustrated and described in the context of process flows and flowcharts.

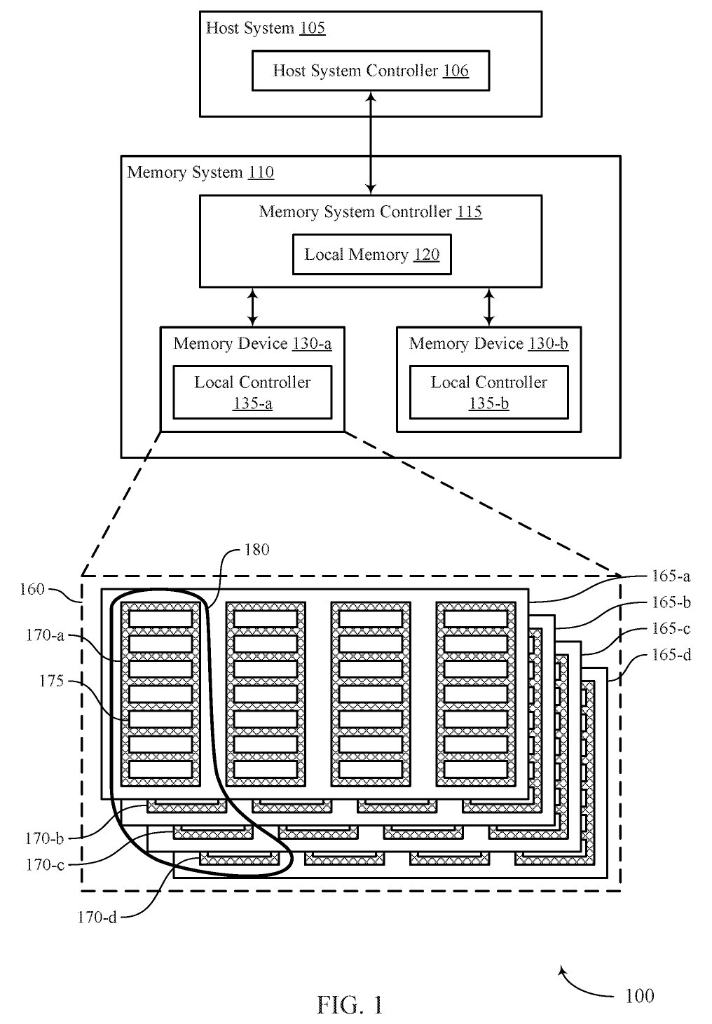

FIG. 1 shows an example of a system 100 that supports data preservation after a supply voltage decrease in a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The memory system 110 may support different write modes, such as a cache-off (also referred to a forced-unit access (FUA)) write mode and a cache-on (or “non-FUA”) write mode. In either write mode, the memory system 110 may use the local memory 120 (also referred to as a local cache memory) to temporarily store write data (e.g., data for writing to the memory devices 130) from the host system 105. In the cache-off write mode, the memory system 110 may wait until the write data has been written to the memory devices 130 before sending confirmation (that the write data has been written) to the host system 105. In the cache-on write mode, the memory system may (e.g., for latency purposes, for timing purposes) send confirmation to the host system 105 before the write data has actually been written to the memory devices 130. That is, in the cache-on write mode, the write data may be written to the memory devices 130 after confirmation has already been sent to the host system 105.

The memory system 110 may have different voltage supplies for different components. For example, the memory system 110 may have a first voltage supply (e.g., VCCQ) for operating the memory system controller 115, and may have a second voltage supply (e.g., VCC) for operating the memory devices 130. If the level of a voltage supply decreases below a threshold level (referred to herein as a supply voltage failure), the memory system 110 may reset and information in the local memory 120 may be lost. For example, if the local memory 120 stores write data and write management information (e.g., sequence-of-write (SOW) information, FTL information). If the memory system 110 is operating in the cache-on write mode and the supply voltage fails, the lost information may be write data that has already been confirmed to the host system 105. If the host system 105 attempts to access the write data after it has been lost (e.g., because the host system 105 is unaware of its loss), the memory system 110 may experience a failure.

To prevent such failures, the memory system 110 (e.g., via the memory system controller 115) may use the techniques described herein to ensure the preservation of cache data (e.g., write data and corresponding write management information) stored in the local memory 120 at the time of a voltage supply failure. In some cases, such preservation may not be possible if the failed voltage supply is the first voltage supply (e.g., because the write data may be lost or corrupted due to the first voltage supply failure), so the memory system 110 may condition the preservation on the voltage supply failure being a failure of the second voltage supply (e.g., VCC). Preservation of the cache data may involve transferring the cache data between a non-retention area of the local memory 120 and a retention area of the local memory 120. To ensure that memory system 110 is aware of the preserved cache data after resetting, the memory system 110 may write a flag, referred to as a preservation flag, to the retention area of the local memory 120. The memory system 110 may check this flag after resetting and, based on (in accordance with) the state of the flag, perform the remaining operations for writing the write data to the memory devices 130.

The system 100 may include any quantity of non-transitory computer readable media that support data preservation after a supply voltage decrease in a memory system. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

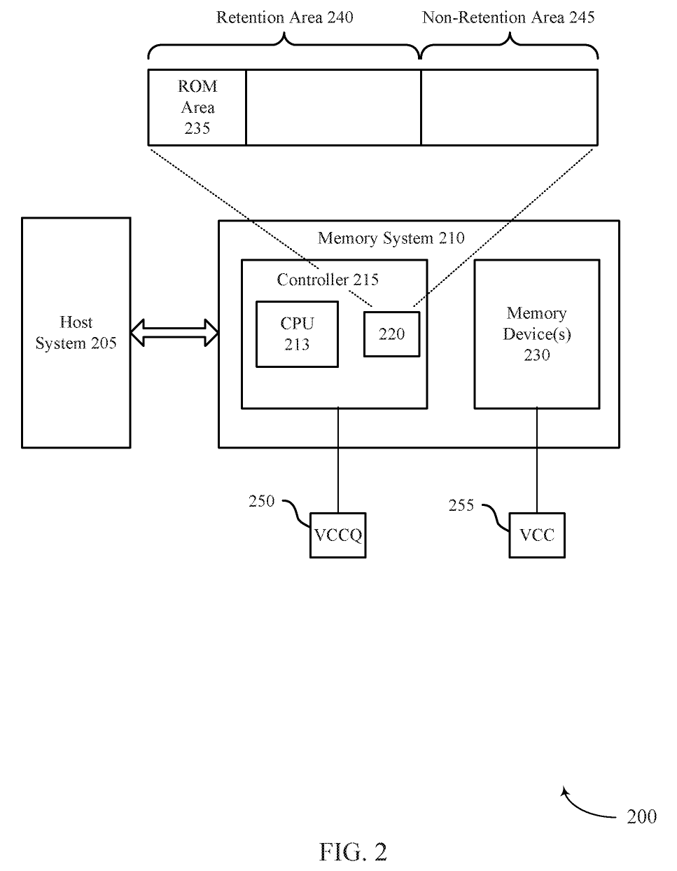

FIG. 2 shows an example of a system 200 that supports data preservation after a supply voltage decrease in a memory system in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more non-volatile memory devices, such as the memory devices 230, to store data transferred between the memory system 210 and the host system 205 (e.g., in response to receiving access commands from the host system 205). The memory devices 230 may include one or more memory devices 130 as described with reference to FIG. 1. The memory system 210 also may include a memory system controller, such as the controller 215, for executing the commands received from the host system 205, which may include controlling the data path components for the moving of the data. The controller 215 may be an example of the memory system controller 115 as described with reference to FIG. 1. The controller 215 may include one or more processors (e.g., CPU 213) that control the various operations of the memory system 210, including operations that facilitate the techniques described herein.

The controller 215 may include a local memory 220, which may be a volatile memory. The local memory 220 may include a retention area 240 and a non-retention area 245. Information stored in the retention area 240 may persist after reset operations whereas information stored in the non-retention area 245 may be lost after reset operations. In some examples, the retention area 240 may backed up to a non-volatile memory whereas the non-retention area may not be backed up to the non-volatile memory. In some examples, the retention area 240 may continue to receive power during reset operations whereas the non-retention area 245 may stop receiving power. In some examples, the retention area 240 may include ROM area 235 which is configured to store firmware code.

The memory system 210 may use the non-retention area 245 to store write data that is received from the host system 205 and intended for the memory device(s) 230. The non-retention area 245 may also store write management information (e.g., SOW information, FTL information) that is used to manage the writing of the write data to the memory device(s) 230. Alternatively, the write management information may be stored in other non-retention storage media, or split between the other non-retention storage media and the non-retention area 245.

The memory system 210 may include or be coupled with one or more voltage supplies that provide power (e.g., supply voltages) to the memory system 210. For example, the memory system 210 may include or be coupled with a first voltage supply 250, which may be configured to output a supply voltage VCCQ to the controller 215. The memory system 210 may also include or be coupled with a second voltage supply 255, which may be configured to output a supply voltage VCC to the memory device(s) 230.

As noted, the non-retention area 245 of the local memory 220 may be used to store write data for the memory devices 230. If a volage supply fails (e.g., if the level supplied by the voltage supply decreases below a threshold value) while the memory system 210 is in the cache-on write mode, the memory system 210 may implement the techniques described herein to prevent loss of write data (e.g., during a reset operation of the memory system 210) that has yet to be written to the memory device(s) 230.

For example, if the failed voltage supply is the second voltage supply 255, the memory system 210 may copy the write data from the non-retention area 245 of the local memory 220 to the retention area 240 of the local memory 220. The memory system 210 may also copy corresponding write management information to the retention area 240 (e.g., from the non-retention area 245, from another non-retention storage media). Copying information from a first storage location to a second storage location may involve reading the information from the first storage location and writing the information to the second storage location. The memory system 210 may write a preservation flag, which may be one or more bits, to the retention area 240 indicating that write data has been preserved in the retention area 240. After resetting, the memory system 210 may copy the write data and the write management information from the retention area 240 to their previous storage locations so that the write data can be written to the memory device(s) 230.

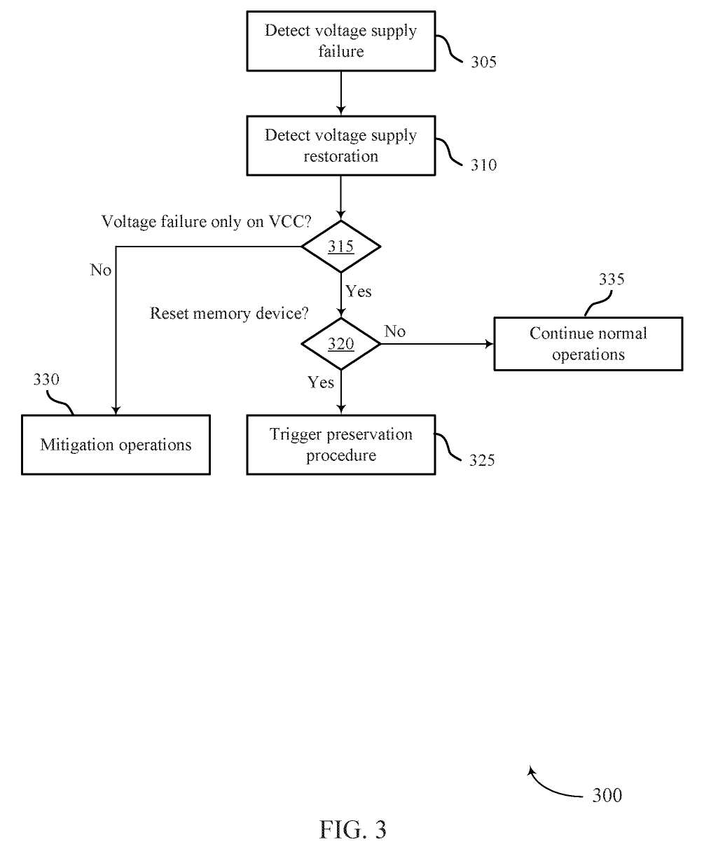

FIG. 3 shows an example of a process flow 300 that supports data preservation after a supply voltage decrease in a memory system in accordance with examples as disclosed herein. The process flow 300 may be an example of a process flow implemented by a memory system as described herein, such as the memory system 210. Implementation of the process flow 300 may allow the memory system 210 to ensure that write data in the local memory 220 is eventually written to the memory device(s) 230, even if the write data is pending in the local memory 220 at the time a voltage supply failure occurs.

Aspects of the process flow 300 may be implemented by one or more controllers, among other components. Additionally or alternatively, aspects of the process flow 300 may be implemented as instructions stored in one or more memories (e.g., firmware stored in one or more memories coupled with the memory system 210). For example, the instructions, if executed by one or more controllers (e.g., the controller 215), may cause the one or more controllers (or a device or a system) to perform the operations of the process flow 300.

At 305, it may be detected (e.g., by the memory system 210) whether there is a voltage supply failure. For example, the memory system 210 may determine that a voltage level provided by a voltage supply has decreased below a threshold level. At 310, it may be detected (e.g., by the memory system 210) that the voltage supply has been restored. For example, the memory system 210 may determine that the voltage level provided by the voltage supply has increased to a threshold level.

At 315, it may be determined (e.g., by the memory system 210) whether the voltage supply failure was only on the second voltage supply 255 (e.g., VCC). If the voltage supply failure was on the first voltage supply 250, or on both the first voltage supply 250 and the second voltage supply 255, the memory system 210 may proceed to 330 and perform mitigation operations. The memory system 210 may proceed to 330, instead of 320, because any write data in the local memory 220 may have been lost or corrupted due to the failure of the first voltage supply 250.

If, at 315, it is determined that the voltage supply failure was only on the second voltage supply 255 (e.g., VCC), the memory system 210 may proceed to 320 and determine whether to perform a reset operation. The memory system 210 may determine to perform a reset operation if the local memory 220 has write data that has been confirmed as being stored in the memory device(s) 230 but that has not yet been stored in the memory device(s) 230. For example, the memory system 210 may determine to perform the reset operation if the local memory 220 has write data that was received in the cache-on write mode and that has not yet been written to the memory device(s) 230.

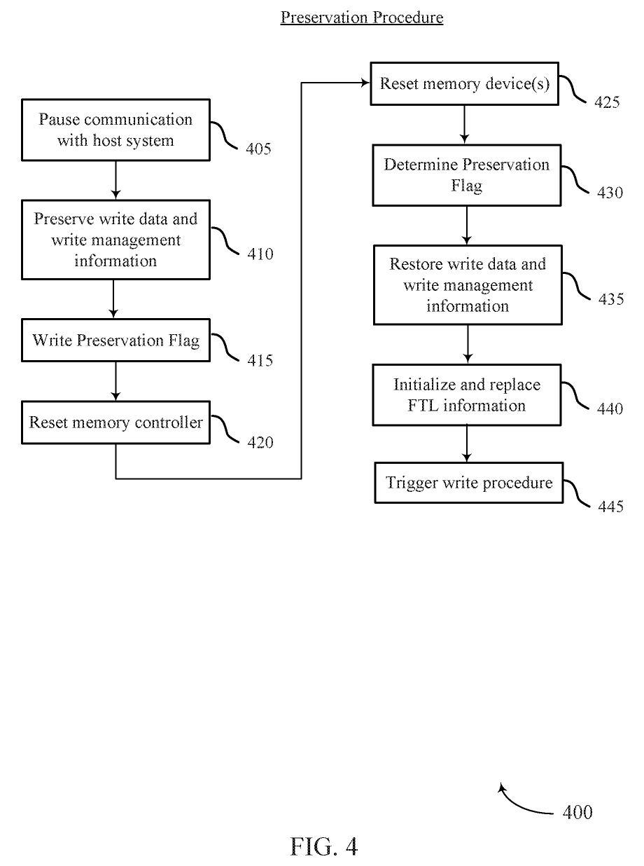

If, at 320, it is determined not to perform the reset operation, the memory system 210 may proceed to 335 and continue normal operations. If, at 320, it is determined to perform the reset operation, the memory system 210 may proceed to 325 and trigger a preservation procedure such as the preservation procedure described with reference to FIG. 4. In some examples, the preservation procedure may also be referred to as a voltage detector (VDT) interrupt procedure or other suitable terminology. The preservation procedure may allow the memory system 210 to preserve the write data (and corresponding write management information) during a reset operation (e.g., a reset operation due to VCC failure) so that the write data can be written to the memory device(s) 230 after the reset operation.

FIG. 4 shows an example of a process flow 400 that supports data preservation after a supply voltage decrease in a memory system in accordance with examples as disclosed herein. The process flow 400 may be an example of a process flow implemented by a memory system as described herein, such as the memory system 210. The process flow 400 may be an example of the preservation procedure triggered at 325 of the process flow 300. The preservation procedure may allow the memory system 210 to preserve the write data (and corresponding write management information) during a reset operation (e.g., a reset operation due to VCC failure) so that the write data can be written to the memory device(s) 230 after the reset operation.

Aspects of the process flow 400 may be implemented by one or more controllers, among other components. Additionally or alternatively, aspects of the process flow 400 may be implemented as instructions stored in one or more memories (e.g., firmware stored in one or more memories coupled with the memory system 210). For example, the instructions, if executed by one or more controllers (e.g., the controller 215), may cause the one or more controllers (or a device or a system) to perform the operations of the process flow 400.

At 405, communications with the host system 205 may be paused (e.g., by the memory system 210). At 410, the write data and the corresponding write management information (SOW information, FTL information) may be preserved (e.g., by the memory system 210). For example, the memory system 210 may write the write data (which may be read from the non-retention area 245 of the local memory 220) to the retention area 240 of the local memory 220. Similarly, the memory system may write the write management information (which may be read from the non-retention area 245 or from another non-retention storage media) to the retention area 240 of the local memory 220. Preserving the write data and the write management information in the retention area 240 may ensure that the write data and the write management information survive (e.g., persist after) an upcoming reset operation for the controller 215.

At 415, the preservation flag may be written (e.g., by the memory system) to the retention area 240. The memory system 210 may write the preservation flag with a logic state that indicates there is write data in the retention area 240 for writing to the memory device(s) 230. Writing the preservation flag may allow the memory system 210 to finish the preservation procedure after the reset operation.

At 420, a reset operation may be performed (e.g., in accordance with the determination at 320) for the controller 215. The reset operation may destroy or corrupt information stored in the non-retention area 245 but not the retention area 240. At 425, a reset operation for the memory device(s) 230 may be performed (e.g., in accordance with the determination at 320).

At 430, the preservation flag may be read from the retention area 240 and it may be determined that the logic state of the preservation flag indicates that there is write data (in the retention area 240) for writing to the memory device(s) 230. Accordingly, at 435, the write data and the write management information may be “restored” by copying the write data from the retention area 240 to the non-retention area 245 and by coping the write management information from the retention area 240 to the non-retention area 245 (or other non-retention storage media). Restoring the write data and the write management information may allow the memory system 210 to write the write data to the memory device(s) 230.

At 440, a first set of FTL information may be initialized based on (e.g., in response to) resetting the controller 215, then replaced (e.g., overwritten) by a second set of FTL information that is part of the write management information. In this way, the memory system 210 may ensure that the correct FTL information (e.g., the FTL information that existed before resetting the controller 215) is used for writing the write data to the memory devices.

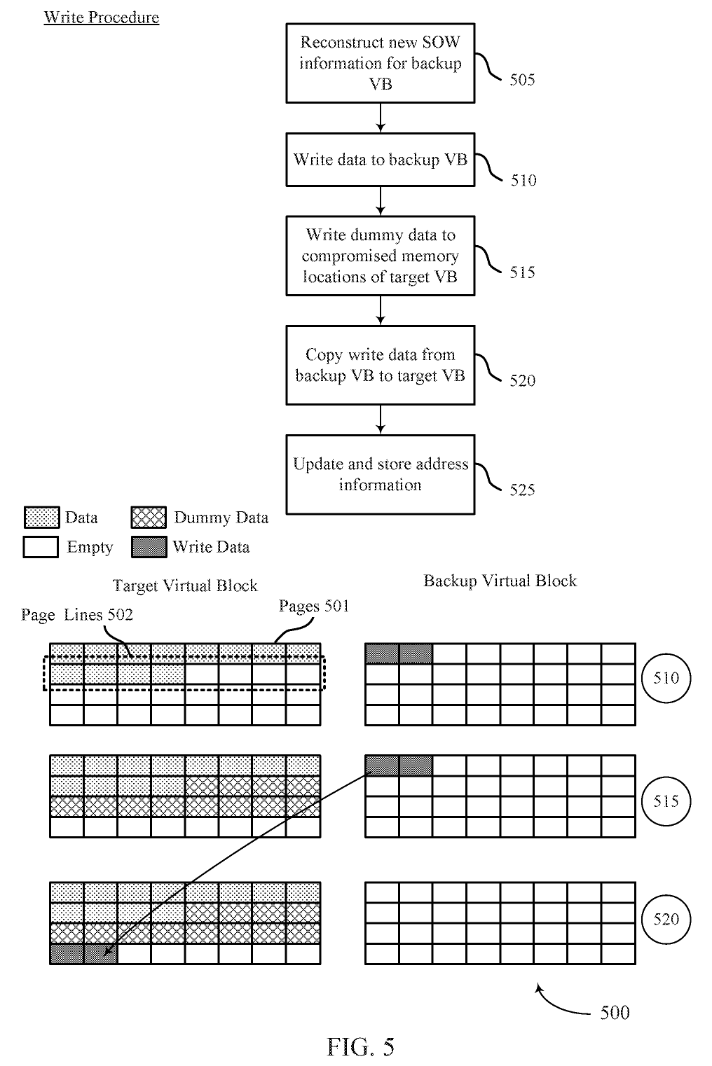

At 445, a write procedure may be triggered such as the write procedure described with reference to FIG. 5. The write procedure may allow the memory system 210 to avoid compromised memory locations during writing the write data to the memory device(s) 230.

FIG. 5 shows an example of a process flow 500 that supports data preservation after a supply voltage decrease in a memory system in accordance with examples as disclosed herein. The process flow 500 may be an example of a process flow implemented by a memory system as described herein, such as the memory system 210. The process flow 500 may be an example of the write procedure triggered at 445 of the process flow 400. The write procedure may allow the memory system 210 to avoid compromised memory locations during writing the write data to the memory device(s) 230. The process flow 500 may refer to target a virtual block (VB) and a backup virtual block. A virtual block may be mapped to memory locations (e.g., pages 501, page lines 502) that are on different planes or dies of a memory device. So, writing to a virtual block may refer to writing to the associated memory locations mapped to that virtual block. The pages mapped to a virtual block may include pages that store data and pages that are empty (e.g., do not store user data). After the process flow 500, the pages may include pages that store the write data and pages that store dummy data.

Aspects of the process flow 500 may be implemented by one or more controllers, among other components. Additionally or alternatively, aspects of the process flow 500 may be implemented as instructions stored in one or more memories (e.g., firmware stored in one or more memories coupled with the memory system 210). For example, the instructions, if executed by one or more controllers (e.g., the controller 215), may cause the one or more controllers (or a device or a system) to perform the operations of the process flow 500.

At 505, new SOW information may be constructed based on (e.g., in accordance with) the SOW information and the FTL information preserved at 410 and restored at 435. The new SOW information may be associated with the backup virtual block as opposed to the original SOW information, which may be associated with the target virtual block. At 510, the write data may be written, in accordance with the new SOW information, to the memory locations (e.g., pages) mapped to the backup virtual block. At 515, dummy data (e.g., random data) may be written to the memory locations of the target virtual block that are associated with the original SOW information. The memory locations may be compromised by the first voltage supply failure and thus may not be suitable for the write data.

At 520, the write data may be copied from the memory locations mapped to the backup virtual block to one or more memory locations mapped to the target virtual block. Thus, the write data may be stored in the memory device(s) 230 in a manner that avoids memory locations that are compromised by the first voltage supply failure. At 525, address information for the write data may be updated and then stored in the memory device(s) 230. For example, the memory system 210 may update a Physical Page Table (PPT) (e.g., sometimes referred to as a L2P table) that maps the addresses of the virtual blocks to physical addresses of the memory locations used to write the write data.

Thus, the write procedure described with reference to process flow 500 may be used to write preserved write data to the memory device(s) 230.

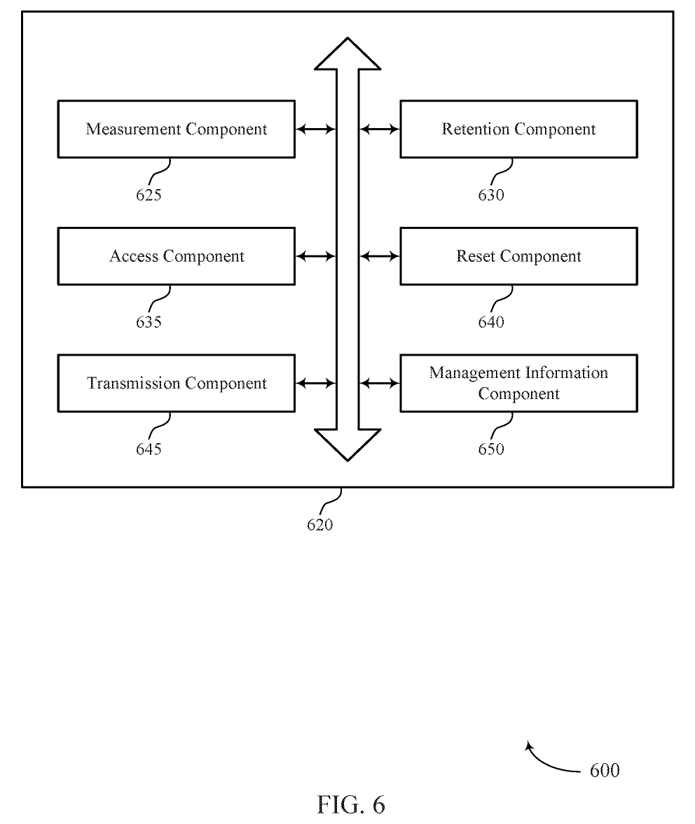

FIG. 6 shows a block diagram 600 of a memory system 620 that supports data preservation after a supply voltage decrease in a memory system in accordance with examples as disclosed herein. The memory system 620 may be an example of aspects of a memory system as described with reference to FIGS. 1 through 5. The memory system 620, or various components thereof, may be an example of means for performing various aspects of data preservation after a supply voltage decrease in a memory system as described herein. For example, the memory system 620 may include a measurement component 625, a retention component 630, an access component 635, a reset component 640, a transmission component 645, a management information component 650, or any combination thereof. Each of these components, or components of subcomponents thereof (e.g., one or more processors, one or more memories), may communicate, directly or indirectly, with one another (e.g., via one or more buses).

The measurement component 625 may be configured as or otherwise support a means for determining that a first supply voltage for a non-volatile memory device of a memory system has decreased below a first threshold level. The retention component 630 may be configured as or otherwise support a means for writing, in response to the first supply voltage having decreased below the first threshold level and in response to a second supply voltage for a controller of the memory system having been maintained above a second threshold level, data from a non-retention area of a volatile memory to a retention area of the volatile memory before resetting the memory system, the data intended for storage in the non-volatile memory device of the memory system. In some examples, the retention component 630 may be configured as or otherwise support a means for writing, after resetting the memory system, the data from the retention area of the volatile memory to the non-retention area of the volatile memory. The access component 635 may be configured as or otherwise support a means for writing, in response to writing the data from the retention area of the volatile memory to the non-retention area of the volatile memory, the data from the non-retention area of the volatile memory to the non-volatile memory device.

In some examples, the retention component 630 may be configured as or otherwise support a means for writing a flag to the retention area of the volatile memory before resetting the memory system and in response to writing the data to the retention area, where the flag indicates that the data has been written to the retention area, and where the data is written from the retention area to the non-retention area in response to the flag.

In some examples, the retention component 630 may be configured as or otherwise support a means for writing, before determining the first supply voltage has decreased below the first threshold level, the data to the non-retention area of the volatile memory in response to a write command. In some examples, the transmission component 645 may be configured as or otherwise support a means for transmitting, before writing the data to the non-volatile memory device, a confirmation that the data has been written to the non-volatile memory device. In some examples, the reset component 640 may be configured as or otherwise support a means for determining to reset the memory system in response to the first supply voltage having decreased below the first threshold level after sending the confirmation and before writing the data to the memory system, where writing the data to the retention area of the volatile memory is based at least in part on determining to reset the memory system.

In some examples, the retention component 630 may be configured as or otherwise support a means for writing, in response to the first supply voltage having decreased below the first threshold level and in response to the second supply voltage having been maintained above the second threshold level, write management information associated with the data to the retention area of the volatile memory.

In some examples, the access component 635 may be configured as or otherwise support a means for writing, after resetting the memory system, the write management information from the retention area of the volatile memory to the non-retention area of the volatile memory, where the data is written to the non-volatile memory device in accordance with the write management information.

In some examples, the write management information includes sequence-of-write (SOW) information or Flash-Translation-Layer (FTL) information or both.

In some examples, the write management information includes a first set of FTL information, and the management information component 650 may be configured as or otherwise support a means for initializing a second set of FTL information in response to resetting the memory system. In some examples, the write management information includes a first set of FTL information, and the management information component 650 may be configured as or otherwise support a means for replacing the second set of FTL information with the first set of FTL information before writing the data to the non-volatile memory device.

In some examples, the reset component 640 may be configured as or otherwise support a means for determining to reset the memory system in response to determining that the data in the non-retention area of the volatile memory yet to be written to the non-volatile memory device, where writing the data to the retention area of the volatile memory is based at least in part on determining to reset the memory system.

In some examples, the reset component 640 may be configured as or otherwise support a means for resetting the controller of the memory system followed by resetting the non-volatile memory device of the memory system.

In some examples, the described functionality of the memory system 620, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 620, or various components thereof, may be implemented at least in part by instructions (e.g., stored in memory, non-transitory computer-readable medium) executable by such at least one processor.

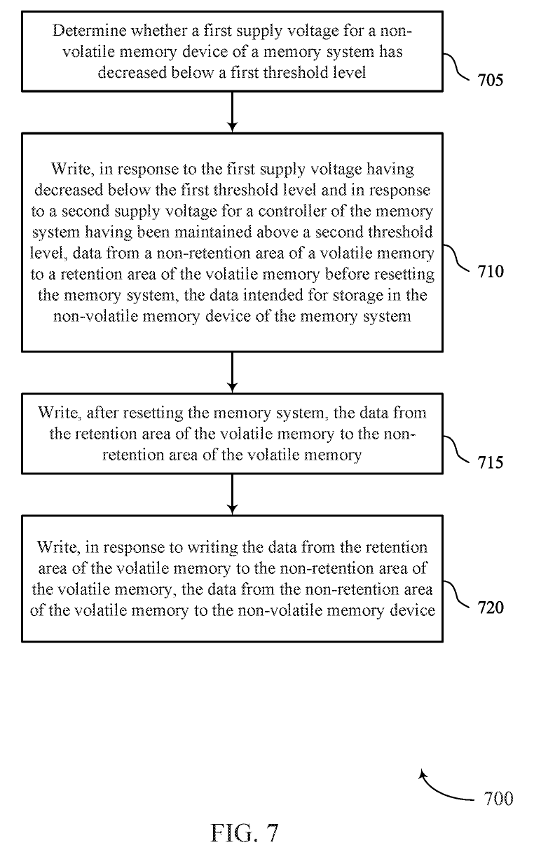

FIG. 7 shows a flowchart illustrating a method 700 that supports data preservation after a supply voltage decrease in a memory system in accordance with examples as disclosed herein. The operations of method 700 may be implemented by a memory system or its components as described herein. For example, the operations of method 700 may be performed by a memory system as described with reference to FIGS. 1 through 6. In some examples, a memory system may execute a set of instructions to control the functional elements of the device to perform the described functions. Additionally, or alternatively, the memory system may perform aspects of the described functions using special-purpose hardware.

At 705, the method may include determining whether a first supply voltage (e.g., VCC) for a non-volatile memory device (e.g., a memory device 230) of a memory system has decreased below a first threshold level. In some examples, aspects of the operations of 705 may be performed by a measurement component 625 as described with reference to FIG. 6.

At 710, the method may include writing, in response to the first supply voltage having decreased below the first threshold level and in response to a second supply voltage (e.g., VCCQ) for a controller of the memory system having been maintained above a second threshold level, data from a non-retention area of a volatile memory (e.g., local memory 220) to a retention area of the volatile memory before resetting the memory system, the data intended for storage in the non-volatile memory device of the memory system. In some examples, aspects of the operations of 710 may be performed by a retention component 630 as described with reference to FIG. 6.

At 715, the method may include writing, after resetting the memory system, the data from the retention area of the volatile memory to the non-retention area of the volatile memory. In some examples, aspects of the operations of 715 may be performed by a retention component 630 as described with reference to FIG. 6.

At 720, the method may include writing, in response to writing the data from the retention area of the volatile memory to the non-retention area of the volatile memory, the data from the non-retention area of the volatile memory to the non-volatile memory device. In some examples, aspects of the operations of 720 may be performed by an access component 635 as described with reference to FIG. 6.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for determining whether a first supply voltage for a non-volatile memory device of a memory system has decreased below a first threshold level; writing, in response to the first supply voltage having decreased below the first threshold level and in response to a second supply voltage for a controller of the memory system having been maintained above a second threshold level, data from a non-retention area of a volatile memory to a retention area of the volatile memory before resetting the memory system, the data intended for storage in the non-volatile memory device of the memory system; writing, after resetting the memory system, the data from the retention area of the volatile memory to the non-retention area of the volatile memory; and writing, in response to writing the data from the retention area of the volatile memory to the non-retention area of the volatile memory, the data from the non-retention area of the volatile memory to the non-volatile memory device.

Aspect 2: The method, apparatus, or non-transitory computer-readable medium of aspect 1, further including operations, features, circuitry, logic, means, or instructions, or any combination thereof for writing a flag to the retention area of the volatile memory before resetting the memory system and in response to writing the data to the retention area, where the flag indicates that the data has been written to the retention area, and where the data is written from the retention area to the non-retention area in response to the flag.

Aspect 3: The method, apparatus, or non-transitory computer-readable medium of aspect 2, further including operations, features, circuitry, logic, means, or instructions, or any combination thereof for writing, before determining the first supply voltage has decreased below the first threshold level, the data to the non-retention area of the volatile memory in response to a write command; transmitting, before writing the data to the non-volatile memory device, a confirmation that the data has been written to the non-volatile memory device; and determining to reset the memory system in response to the first supply voltage having decreased below the first threshold level after sending the confirmation and before writing the data to the memory system, where writing the data to the retention area of the volatile memory is based at least in part on determining to reset the memory system.

Aspect 4: The method, apparatus, or non-transitory computer-readable medium of any of aspects 1 through 3, further including operations, features, circuitry, logic, means, or instructions, or any combination thereof for writing, in response to the first supply voltage having decreased below the first threshold level and in response to the second supply voltage having been maintained above the second threshold level, write management information associated with the data to the retention area of the volatile memory.

Aspect 5: The method, apparatus, or non-transitory computer-readable medium of aspect 4, further including operations, features, circuitry, logic, means, or instructions, or any combination thereof for writing, after resetting the memory system, the write management information from the retention area of the volatile memory to the non-retention area of the volatile memory, where the data is written to the non-volatile memory device in accordance with the write management information.

Aspect 6: The method, apparatus, or non-transitory computer-readable medium of any of aspects 4 through 5, where the write management information includes SOW information or FTL information or both.

Aspect 7: The method, apparatus, or non-transitory computer-readable medium of any of aspects 4 through 6, where the write management information includes a first set of FTL information and the method, apparatuses, and non-transitory computer-readable medium further includes operations, features, circuitry, logic, means, or instructions, or any combination thereof for initializing a second set of FTL information in response to resetting the memory system and replacing the second set of FTL information with the first set of FTL information before writing the data to the non-volatile memory device.

Aspect 8: The method, apparatus, or non-transitory computer-readable medium of any of aspects 1 through 7, further including operations, features, circuitry, logic, means, or instructions, or any combination thereof for determining to reset the memory system in response to determining that the data in the non-retention area of the volatile memory yet to be written to the non-volatile memory device, where writing the data to the retention area of the volatile memory is based at least in part on determining to reset the memory system.

Aspect 9: The method, apparatus, or non-transitory computer-readable medium of any of aspects 1 through 8, further including operations, features, circuitry, logic, means, or instructions, or any combination thereof for resetting the controller of the memory system followed by resetting the non-volatile memory device of the memory system.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

As used herein, the term “substantially” means that the modified characteristic (e.g., a verb or adjective modified by the term substantially) need not be absolute but is close enough to achieve the advantages of the characteristic.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more non-volatile memory devices; and
processing circuitry coupled with the one or more non-volatile memory devices and configured to cause the memory system to:
determine whether a first supply voltage for a non-volatile memory device of the memory system has decreased below a first threshold level;
write, in response to the first supply voltage having decreased below the first threshold level and in response to a second supply voltage for a controller of the memory system having been maintained above a second threshold level, data from a non-retention area of a volatile memory to a retention area of the volatile memory before resetting the memory system, the data intended for storage in the one or more non-volatile memory devices of the memory system;
write, after resetting the memory system, the data from the retention area of the volatile memory to the non-retention area of the volatile memory; and
write, in response to writing the data from the retention area of the volatile memory to the non-retention area of the volatile memory, the data from the non-retention area of the volatile memory to the one or more non-volatile memory devices.

2. The memory system of claim 1, wherein the processing circuitry is further configured to cause the memory system to:
write a flag to the retention area of the volatile memory before resetting the memory system and in response to writing the data to the retention area, wherein the flag indicates that the data has been written to the retention area, and wherein the data is written from the retention area to the non-retention area in response to the flag.

3. The memory system of claim 2, wherein the processing circuitry is further configured to cause the memory system to:
write, before determining the first supply voltage has decreased below the first threshold level, the data to the non-retention area of the volatile memory in response to a write command;
transmit, before writing the data to the one or more non-volatile memory devices, a confirmation that the data has been written to the one or more non-volatile memory devices; and
determine to reset the memory system in response to the first supply voltage having decreased below the first threshold level after sending the confirmation and before writing the data to the memory system, wherein writing the data to the retention area of the volatile memory is based at least in part on determining to reset the memory system.

4. The memory system of claim 1, wherein the processing circuitry is further configured to cause the memory system to:
write, in response to the first supply voltage having decreased below the first threshold level and in response to the second supply voltage having been maintained above the second threshold level, write management information associated with the data to the retention area of the volatile memory.

5. The memory system of claim 4, wherein the processing circuitry is further configured to cause the memory system to:
write, after resetting the memory system, the write management information from the retention area of the volatile memory to the non-retention area of the volatile memory, wherein the data is written to the one or more non-volatile memory devices in accordance with the write management information.

6. The memory system of claim 4, wherein the write management information comprises sequence-of-write (SOW) information or Flash-Translation-Layer (FTL) information or both.

7. The memory system of claim 4, wherein the write management information comprises a first set of Flash-Translation-Layer (FTL) information, and the processing circuitry is further configured to cause the memory system to:
initialize a second set of FTL information in response to resetting the memory system; and
replace the second set of FTL information with the first set of FTL information before writing the data to the one or more non-volatile memory devices.

8. The memory system of claim 1, wherein the processing circuitry is further configured to cause the memory system to:
determine to reset the memory system in response to determining that the data in the non-retention area of the volatile memory yet to be written to the one or more non-volatile memory devices, wherein writing the data to the retention area of the volatile memory is based at least in part on determining to reset the memory system.

9. The memory system of claim 1, wherein the processing circuitry is further configured to cause the memory system to:
reset the controller of the memory system followed by resetting the one or more non-volatile memory devices of the memory system.

10. A non-transitory computer-readable medium storing code, the code comprising instructions executable by one or more processors to cause a memory system to:
determine whether a first supply voltage for a non-volatile memory device of the memory system has decreased below a first threshold level;
write, in response to the first supply voltage having decreased below the first threshold level and in response to a second supply voltage for a controller of the memory system having been maintained above a second threshold level, data from a non-retention area of a volatile memory to a retention area of the volatile memory before resetting the memory system, the data intended for storage in the non-volatile memory device of the memory system;
write, after resetting the memory system, the data from the retention area of the volatile memory to the non-retention area of the volatile memory; and
write, in response to writing the data from the retention area of the volatile memory to the non-retention area of the volatile memory, the data from the non-retention area of the volatile memory to the non-volatile memory device.

11. The non-transitory computer-readable medium of claim 10, wherein the instructions are further executable by the one or more processors to cause the memory system to:
write a flag to the retention area of the volatile memory before resetting the memory system and in response to writing the data to the retention area, wherein the flag indicates that the data has been written to the retention area, and wherein the data is written from the retention area to the non-retention area in response to the flag.

12. The non-transitory computer-readable medium of claim 11, wherein the instructions are further executable by the one or more processors to cause the memory system to:
write, before determining the first supply voltage has decreased below the first threshold level, the data to the non-retention area of the volatile memory in response to a write command;
transmit, before writing the data to the non-volatile memory device, a confirmation that the data has been written to the non-volatile memory device; and
determine to reset the memory system in response to the first supply voltage having decreased below the first threshold level after sending the confirmation and before writing the data to the memory system, wherein writing the data to the retention area of the volatile memory is based at least in part on determining to reset the memory system.

13. The non-transitory computer-readable medium of claim 10, wherein the instructions are further executable by the one or more processors to cause the memory system to:
write, in response to the first supply voltage having decreased below the first threshold level and in response to the second supply voltage having been maintained above the second threshold level, write management information associated with the data to the retention area of the volatile memory.

14. The non-transitory computer-readable medium of claim 13, wherein the instructions are further executable by the one or more processors to cause the memory system to:
write, after resetting the memory system, the write management information from the retention area of the volatile memory to the non-retention area of the volatile memory, wherein the data is written to the non-volatile memory device in accordance with the write management information.

15. The non-transitory computer-readable medium of claim 13, wherein the write management information comprises sequence-of-write (SOW) information or Flash-Translation-Layer (FTL) information or both.

16. The non-transitory computer-readable medium of claim 13, wherein the write management information comprises a first set of Flash-Translation-Layer (FTL) information, and the instructions are further executable by the one or more processors to cause the memory system to:
initialize a second set of FTL information in response to resetting the memory system; and
replace the second set of FTL information with the first set of FTL information before writing the data to the non-volatile memory device.

17. The non-transitory computer-readable medium of claim 10, wherein the instructions are further executable by the one or more processors to cause the memory system to:
determine to reset the memory system in response to determining that the data in the non-retention area of the volatile memory yet to be written to the non-volatile memory device, wherein writing the data to the retention area of the volatile memory is based at least in part on determining to reset the memory system.

18. The non-transitory computer-readable medium of claim 10, wherein the instructions are further executable by the one or more processors to cause the memory system to:
reset the controller of the memory system followed by resetting the non-volatile memory device of the memory system.

19. A method, comprising:
determining whether a first supply voltage for a non-volatile memory device of a memory system has decreased below a first threshold level;
writing, in response to the first supply voltage having decreased below the first threshold level and in response to a second supply voltage for a controller of the memory system having been maintained above a second threshold level, data from a non-retention area of a volatile memory to a retention area of the volatile memory before resetting the memory system, the data intended for storage in the non-volatile memory device of the memory system;
writing, after resetting the memory system, the data from the retention area of the volatile memory to the non-retention area of the volatile memory; and
writing, in response to writing the data from the retention area of the volatile memory to the non-retention area of the volatile memory, the data from the non-retention area of the volatile memory to the non-volatile memory device.

20. The method of claim 19, further comprising:
writing a flag to the retention area of the volatile memory before resetting the memory system and in response to writing the data to the retention area, wherein the flag indicates that the data has been written to the retention area, and wherein the data is written from the retention area to the non-retention area in response to the flag.

21. The method of claim 20, further comprising:
writing, before determining the first supply voltage has decreased below the first threshold level, the data to the non-retention area of the volatile memory in response to a write command;
transmitting, before writing the data to the non-volatile memory device, a confirmation that the data has been written to the non-volatile memory device; and
determining to reset the memory system in response to the first supply voltage having decreased below the first threshold level after sending the confirmation and before writing the data to the memory system, wherein writing the data to the retention area of the volatile memory is based at least in part on determining to reset the memory system.

22. The method of claim 19, further comprising:
writing, in response to the first supply voltage having decreased below the first threshold level and in response to the second supply voltage having been maintained above the second threshold level, write management information associated with the data to the retention area of the volatile memory.

23. The method of claim 22, further comprising:
writing, after resetting the memory system, the write management information from the retention area of the volatile memory to the non-retention area of the volatile memory, wherein the data is written to the non-volatile memory device in accordance with the write management information.

24. The method of claim 22, wherein the write management information comprises sequence-of-write (SOW) information or Flash-Translation-Layer (FTL) information or both.

25. The method of claim 22, wherein the write management information comprises a first set of Flash-Translation-Layer (FTL) information, the method further comprising:
initializing a second set of FTL information in response to resetting the memory system; and
replacing the second set of FTL information with the first set of FTL information before writing the data to the non-volatile memory device.
